(19) United States
(12) Patent Application Publication
(10) Pub. No.: US 2024/0145462 A1
(43) Pub. Date: May 2, 2024

(54) ELECTROSTATIC DISCHARGE CONTROL DEVICES

(71) Applicant: GlobalFoundries Singapore Pte. Ltd., Singapore (SG)

(72) Inventors: Kyongjin Hwang, Singapore (SG); Alwyn Rebello, Singapore (SG); Jie Zeng, Singapore (SG)

(21) Appl. No.: 17/974,823

(22) Filed: Oct. 27, 2022

(51) Int. Cl. H01L 27/02; H01L 29/737; H02H 9/04

(52) U.S. Cl. CPC H01L 27/0259; H01L 29/7371; H02H 9/046

(57) ABSTRACT

Structures for an electrostatic discharge control device and methods of forming same. The structure comprises a shallow trench isolation region positioned in a semiconductor substrate, and a heterojunction bipolar transistor structure. The heterojunction bipolar transistor structure includes a collector in the semiconductor substrate, an emitter, and a base positioned between a first portion of the collector and the emitter. The collector has a first conductivity type, the collector extends to a top surface of the semiconductor substrate, and the collector wraps about the shallow trench isolation region. The structure further comprises a doped region positioned in the collector adjacent to the shallow trench isolation region. The doped region has a second conductivity type opposite to the first conductivity type, and a second portion of the collector is positioned between the doped region and the top surface of the semiconductor substrate.

### BACKGROUND

The disclosure relates generally to semiconductor devices and integrated circuit fabrication and, more specifically, to structures for an electrostatic discharge control device and methods of forming same.

An integrated circuit may be exposed to random electrostatic discharge (ESD) events that can direct potentially large and damaging ESD currents to the sensitive devices of the integrated circuit. An ESD event refers to an unpredictable electrical discharge of a positive or negative current over a short duration and during which a large amount of current is directed toward the integrated circuit. An ESD event may occur during post-manufacture chip handling or after chip installation on a circuit board or other carrier. An ESD event may originate from a variety of sources, such as the human body, a machine component, or a chip carrier.

Precautions may be taken to protect the integrated circuit from an ESD event. One such precaution is an on-chip protection circuit that is designed to avert damage to the sensitive devices of the integrated circuit during an ESD event. If an ESD event occurs, a protection device of the protection circuit is triggered to enter a low-impedance state that conducts the ESD current to ground and thereby shunts the ESD current away from the sensitive devices of the integrated circuit. The protection device remains clamped in its low-impedance state until the ESD current is drained and the ESD voltage is discharged to an acceptable level.

Improved structures for an electrostatic discharge control device and methods of forming same are needed.

### SUMMARY

In an embodiment, a structure for an electrostatic discharge device is provided. The structure comprises a semiconductor substrate including a top surface, a shallow trench isolation region positioned in the semiconductor substrate, and a heterojunction bipolar transistor structure. The heterojunction bipolar transistor structure includes a collector in the semiconductor substrate, an emitter, and a base positioned between a first portion of the collector and the emitter. The collector has a first conductivity type, the collector extends to the top surface of the semiconductor substrate, and the collector wraps about the shallow trench isolation region. The structure further comprises a doped region positioned in the collector adjacent to the shallow trench isolation region. The doped region has a second conductivity type opposite to the first conductivity type, and a second portion of the collector is positioned between the doped region and the top surface of the semiconductor substrate.

In an embodiment, a method of forming a structure for an electrostatic discharge device is provided. The method comprises forming a shallow trench isolation region in a semiconductor substrate, and forming a heterojunction bipolar transistor structure. The heterojunction bipolar transistor structure includes a collector in the semiconductor substrate, an emitter, and a base positioned between a first portion of the collector and the emitter. The collector has a first conductivity type, the collector extends to a top surface of the semiconductor substrate, and the collector wraps about the shallow trench isolation region. The method further comprises forming a doped region in the collector adjacent to the shallow trench isolation region. The doped region has a second conductivity type opposite to the first conductivity type, and a second portion of the collector is positioned between the doped region and the top surface of the semiconductor substrate.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals are used to indicate like features in the various views.

FIG. 1 is a cross-sectional view of a structure in accordance with embodiments of the invention.

FIG. 2 is a cross-sectional view of the structure at a fabrication stage subsequent to FIG. 1.

FIG. 3 is a cross-sectional view of a structure in accordance with alternative embodiments of the invention.

FIG. 4 is a cross-sectional view of a structure in accordance with alternative embodiments of the invention.

FIG. 5 is a cross-sectional view of a structure in accordance with alternative embodiments of the invention.

FIG. 6 is a cross-sectional view of a structure in accordance with alternative embodiments of the invention.

### DETAILED DESCRIPTION

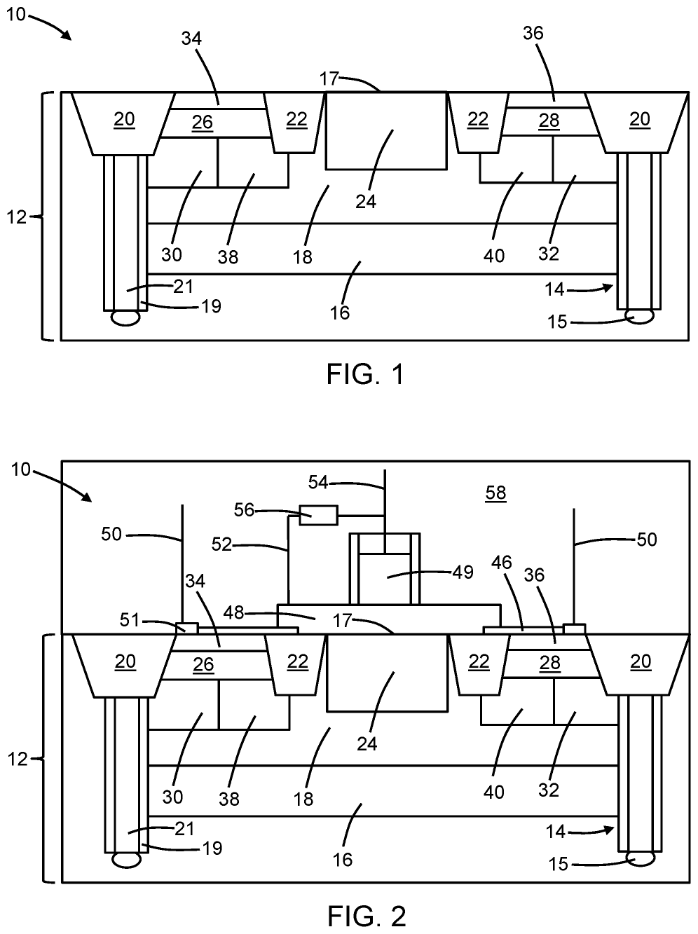

With reference to FIG. 1 and in accordance with embodiments of the invention, a device structure 10 for an electrostatic discharge device includes a semiconductor substrate 12, a deep trench isolation region 14, a deep well 16, and shallow trench isolation regions 20, 22. The semiconductor substrate 12 includes a semiconductor layer 18 that is surrounded on multiple sides by the deep trench isolation region 14 and deep well 16. The semiconductor substrate 12 may be comprised of a semiconductor material, such as single-crystal silicon. The semiconductor layer 18, which may be epitaxially grown, may be doped to have a conductivity type that is opposite to the conductivity type of the portion of semiconductor substrate 12 surrounding the deep trench isolation region 14, deep well 16, and shallow trench isolation regions 20. In an embodiment, the semiconductor layer 18 may be comprised of a semiconductor material, such as single-crystal silicon, that is doped to have n-type conductivity.

The deep trench isolation region 14 may be formed by patterning a trench in the semiconductor substrate 12, lining the trench with a dielectric collar 19, and filling the trench with a conductor layer 21. The dielectric collar 19 may be comprised of, for example, silicon dioxide, and the conductor layer 21 may be comprised of a conductor, such as doped polysilicon. The deep trench isolation region 14 may adjoin the shallow trench isolation regions 20. A doped region 15 may be formed by ion implantation at the base of the trench before forming the dielectric collar 19 and the conductor layer 21. In an embodiment, the doped region 15 may be doped with a concentration of a p-type dopant (e.g., boron) to provide p-type conductivity.

The deep well 16 is doped to have the same conductivity type as the semiconductor layer 18 but at a higher dopant concentration. In an embodiment, the deep well 16 may be doped with a concentration of an n-type dopant (e.g., arsenic or phosphorus) to provide n-type conductivity. In an embodiment, the deep well 16 may be formed by introducing a dopant by, for example, ion implantation into the semiconductor substrate 12. The implantation conditions (e.g., ion species, dose, kinetic energy) may be selected to tune the electrical and physical characteristics of the deep well 16. The deep trench isolation region 14, deep well 16, and shallow trench isolation regions 20 electrically isolate the semiconductor layer 18 from the oppositely-doped portion of the semiconductor substrate 12 surrounding the deep trench isolation region 14, deep well 16, and shallow trench isolation regions 20. The electrical isolation provided by the deep trench isolation region 14, deep well 16, and shallow trench isolation regions 20 may enable broad current flow during operation of the electrostatic discharge device.

The shallow trench isolation regions 20 are arranged at the boundary between the semiconductor substrate 12 and the semiconductor layer 18, and the shallow trench isolation regions 22 are arranged in the semiconductor layer 18. The shallow trench isolation regions 20, 22 may be formed by patterning shallow trenches with lithography and etching processes, depositing a dielectric material, such as silicon dioxide, in the shallow trenches, and planarizing and/or recessing the deposited dielectric material.

A well 24 may be positioned in the semiconductor layer 18 interior of the shallow trench isolation regions 22. Doped regions 26, 28 may be positioned in the semiconductor layer 18 laterally between the shallow trench isolation regions 20 and the shallow trench isolation regions 22. A well 30 may be positioned in the semiconductor layer 18 beneath the doped region 26, and a well 32 may be positioned in the semiconductor layer 18 beneath the doped region 28. The doped region 26 is positioned in a vertical direction between the well 30 and a top surface 17 of the semiconductor substrate 12, and the doped region 28 is positioned in a vertical direction between the well 32 and the top surface 17. A doped region 34 is positioned between the doped region 26 and the top surface 17. A doped region 36 is positioned between the doped region 28 and the top surface 17. The doped regions 34, 36 may be coextensive (i.e., share a boundary) with the top surface 17.

In an embodiment, the well 24, the doped regions 26, 28, the wells 30, 32, and the doped regions 34, 36 may be doped with a concentration of an n-type dopant (e.g., arsenic or phosphorus) to provide n-type conductivity. The doped regions 34, 36 may have a higher dopant concentration than the doped regions 26, 28, the doped regions 26, 28 may have a higher dopant concentration than the wells 30, 32, and the well 24 and the wells 30, 32 may have a higher dopant concentration than the semiconductor layer 18. The semiconductor layer 18, the well 24, the doped regions 26, 28, the wells 30, 32, and the doped regions 34, 36 may represent components of a collector of a heterojunction bipolar transistor structure, and the collector may be considered to wrap about the shallow trench isolation regions 22 by being physically located on multiple sides of the collector.

The well 24 may be formed by selectively implanting ions, such as ions including the n-type dopant, with an implantation mask having an opening defining the intended location for the well 24 in the semiconductor layer 18. The doped regions 26, 28 may be concurrently formed by selectively implanting ions, such as ions including the n-type dopant, with an implantation mask having openings defining the intended locations for the doped regions 26, 28 in the semiconductor layer 18. The wells 30, 32 may be concurrently formed by selectively implanting ions, such as ions including the n-type dopant, with an implantation mask having openings defining the intended locations for the wells 30, 32 in the semiconductor layer 18. The doped regions 34, 36 may be concurrently formed by selectively implanting ions, such as ions including the n-type dopant, with an implantation mask having openings defining the intended locations for the doped regions 34, 36 in the semiconductor layer 18.

Doped regions 38, 40 are positioned in the semiconductor layer 18. The doped regions 38, 40 may be formed by introducing a dopant of a given conductivity type by, for example, ion implantation into the semiconductor layer 18. A patterned implantation mask may be formed to define selected areas on the top surface 17 of the semiconductor layer 18 that are exposed for the implantation of ions. The implantation mask may include a layer of an organic photoresist that is applied and patterned to form openings exposing the selected areas on the top surface 17 of the semiconductor layer 18 and determining, at least in part, the location and horizontal dimensions of the doped regions 38, 40. The implantation mask has a thickness and stopping power sufficient to block the implantation of ions in masked areas. The implantation conditions (e.g., ion species, dose, kinetic energy) may be selected to tune the electrical and physical characteristics of the doped regions 38, 40. The doped regions 38, 40 are doped to have an opposite conductivity type from the collector defined by the semiconductor layer 18, the doped regions 26, 28, the wells 30, 32, and the doped regions 34, 36. In an embodiment, the doped regions 38, 40 may be doped with a concentration of a p-type dopant (e.g., boron) to provide p-type conductivity.

In an embodiment, the doped regions 38, 40 may abut the shallow trench isolation regions 22. In an embodiment, the doped region 38 may adjoin a sidewall of the adjacent shallow trench isolation region 22 and extend beneath a portion of the bottom of the adjacent shallow trench isolation region 22, and the doped region 40 may adjoin a sidewall of the adjacent shallow trench isolation region 22 and extend beneath a portion of a bottom of the adjacent shallow trench isolation regions 22. In an embodiment, the well 30 may be positioned in a lateral direction between the doped region 38 and the adjacent shallow trench isolation region 20, and the well 32 may be positioned in a lateral direction between the doped region 40 and the adjacent shallow trench isolation region 20. In an embodiment, the doped region 38 may be positioned in a lateral direction between the well 30 and the adjacent shallow trench isolation region 22, and the doped region 40 may be positioned in a lateral direction between the well 32 and the adjacent shallow trench isolation region 22. The doped region 26 and the doped region 34 are positioned in a vertical direction between the doped region 38 and the top surface 17 and in a vertical direction between the well 30 and the top surface 17. The doped region 28 and the doped region 36 are positioned in a vertical direction between the doped region 40 and the top surface 17 and in a vertical direction between the well 32 and the top surface 17.

With reference to FIG. 2 in which like reference numerals refer to like features in FIG. 1 and at a subsequent fabrication stage, a dielectric layer 46 may include a section positioned on the top surface 17 of the semiconductor substrate 12 over the doped region 34 and a section positioned on the top surface 17 of the semiconductor substrate 12 over the doped region 36. The dielectric layer 46 may be comprised of a dielectric material, such as silicon nitride, that is deposited and then patterned by lithography and etching processes to form the sections. One section of the dielectric layer 46 has an overlapping relationship with a portion of the doped region 34 and the shallow trench isolation region 22 adjacent to the doped region 34. Another section of the dielectric layer 46 has an overlapping relationship with a portion of the doped region 36 and the shallow trench isolation region 22 adjacent to the doped region 36. Other portions of the doped regions 34, 36, which are adjacent to the shallow trench isolation regions 20, are not covered by the sections of the dielectric layer 46. The sections of the dielectric layer 46 may function as a silicide-blocking layer.

A semiconductor layer 48 is positioned on the top surface 17 of the semiconductor substrate 12 over the semiconductor layer 18. The semiconductor layer 48, which abuts the well 24 at the top surface 17, may contain single-crystal semiconductor material that is formed by an epitaxial growth process. In an embodiment, the semiconductor material of the semiconductor layer 48 may be comprised of silicon-germanium. In an embodiment, the semiconductor material of the semiconductor layer 48 may be comprised of silicon-germanium a silicon content ranging from 95 atomic percent to 50 atomic percent and a germanium content ranging from 5 atomic percent to 50 atomic percent. In an alternative embodiment, the semiconductor layer 48 may have a germanium content that is graded or stepped in a vertical direction, which may be accomplished during epitaxial growth by varying the reactants. In an embodiment, the semiconductor layer 48 may include a layer stack in which a sublayer containing germanium is positioned in a vertical direction between sublayers that lack a germanium content.

The semiconductor layer 48 may be doped to have an opposite conductivity type from the well 24. In an embodiment, the semiconductor layer 48 may be in situ doped during epitaxial growth with a concentration of a dopant, such as a p-type dopant (e.g., boron) that provides p-type conductivity. In an embodiment, the semiconductor material of the semiconductor layer 48 may be uniformly doped with a p-type dopant. In an embodiment, the semiconductor layer 48 may be in situ doped during epitaxial growth with a concentration of carbon that may suppress diffusion of the p-type dopant. In an embodiment, the semiconductor layer 48 may directly contact the semiconductor substrate 12 to define a p-n junction with the well 24. The semiconductor layer 48 may represent a base of a heterojunction bipolar transistor structure.

A semiconductor layer 49 is positioned on a portion of the semiconductor layer 48 and has an opposite conductivity type from the semiconductor layer 48. The semiconductor layer 49 may be formed by depositing a blanket semiconductor layer and patterning the blanket semiconductor layer with lithography and etching processes. The semiconductor layer 49 may be comprised of a semiconductor material, such as polycrystalline silicon. In an embodiment, the semiconductor layer 49 may be doped with an n-type dopant (e.g., phosphorus or arsenic) to provide n-type conductivity. The semiconductor layer 49 may represent an emitter of a heterojunction bipolar transistor structure.

The device structure 10 may include an interconnect structure 58 formed by middle-of-line processing and back-end-of-line processing. The interconnect structure 58 may include electrical connections 50, 52, 54 that are coupled to the electrostatic discharge device. The electrical connections 50, 52, 54 may include metal features that are disposed in one or more dielectric layers of the interconnect structure 58.

The electrical connections 50 are physically and electrically connected to sections of a silicide layer 51 located on the portions of the doped regions 34, 36 that are not covered by the sections of the dielectric layer 46. The presence of the sections of the dielectric layer 46, which cover respective portions of the doped regions 34, 36, may be effective to improve the electrostatic discharge current capacity of the electrostatic discharge device. The sections of the dielectric layer 46 are positioned in a lateral direction between the sections of the silicide layer 51 and the semiconductor layer 48.

The electrical connection 52 is physically and electrically connected to the semiconductor layer 48. The electrical connection 54 is physically and electrically connected to the semiconductor layer 49. The semiconductor layer 48 is connected to the semiconductor layer 49 by the electrical connection 52, which includes a triggering circuit 56. In an embodiment, the triggering circuit 56 may include a resistor, such as a ten kiloohm resistor, that is located in the electrical connection 52 between the semiconductor layer 48 and the semiconductor layer 49. The presence of the resistor in the triggering circuit 56 may enhance the ability of the electrostatic discharge device to respond to an electrostatic discharge event. In alternative embodiments, the triggering circuit 56 may further include an additional bipolar junction transistor, an additional capacitor, and/or an additional resistor.

The device structure 10 for the electrostatic discharge device may be characterized as a heterojunction bipolar transistor structure that includes an emitter represented by the semiconductor layer 49, a base represented by the semiconductor layer 48, and a collector collectively represented by the semiconductor layer 18, the well 24, the doped regions 26, 28, the wells 30, 32, and the doped regions 34, 36. The components of the collector are all doped to have the same conductivity type (e.g., n-type conductivity) but with various different dopant concentrations among the different components. The collector is doped to have the same conductivity type as the emitter and an opposite conductivity type from the base.

The doped regions 38, 40, which have an opposite conductivity type from the collector, are included in the electrostatic discharge device and are embedded in the collector of the heterojunction bipolar transistor structure. The doped regions 38, 40 are electrically floating because of, for example, an absence of a direct electrical connection in the interconnect structure 58. In addition to being spaced from the top surface 17 and separated from the top surface by a portion of the collector, the doped regions 38, 40 are positioned in a vertical direction beneath the portions of the doped regions 34, 36 that are covered by the sections of the dielectric layer 46. The presence of the electrically-floating doped regions 38, 40 may enhance the current performance of the electrostatic discharge device.

The collector of the heterojunction bipolar transistor structure wraps about the shallow trench isolation regions 22 in that the collector is located in a space between the shallow trench isolation regions 22, in a space between the shallow trench isolation regions 20 and the shallow trench isolation regions 22, and in a space beneath the shallow trench isolation regions 22. The collector extends in a vertical direction to the top surface 17 on both sides of the shallow trench isolation regions 22. The deep trench isolation region 14 extends in a vertical direction to a greater depth in the semiconductor substrate 12 than the collector.

The semiconductor layer 48 representing the base of the heterojunction bipolar transistor structure is located between a portion of the collector (i.e., the well 24) interior of the shallow trench isolation regions 22 and the semiconductor layer 49 representing the emitter of the heterojunction bipolar transistor structure. Respective portions of the collector (i.e., the doped regions 26, 28 and the doped regions 34, 36) are positioned in a vertical direction between the top surface 17 and each of the doped regions 38, 40. In an embodiment, these portions of the collector may fully separate the doped regions 38, 40 from the top surface 17. Respective portions of the collector (i.e., the wells 30, 32) are also positioned in a lateral direction between the doped regions 38, 40 and the shallow trench isolation regions 20.

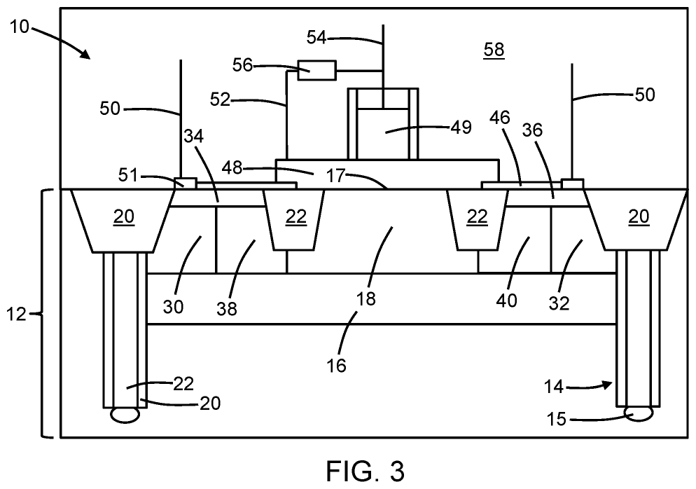

With reference to FIG. 3 in which like reference numerals refer to like features in FIG. 2 and in accordance with alternative embodiments of the invention, the doped regions 26, 28 may be eliminated from the device structure 10. As a result, the well 30 and the doped region 38 may abut the doped region 34, and the well 32 and the doped region 40 may abut the doped region 36. The well 24 may also be eliminated from the portion of the semiconductor layer 18 that is interior of the shallow trench isolation regions 22. The dopant concentration of the deep well 16 may be increased, and the deep well 16 may be positioned closer to the semiconductor layer 48. In an embodiment, the deep well 16 may abut the wells 30, 32 and the doped regions 38, 40. The modifications to the deep well 16 may be effective to increase the breakdown voltage of the electrostatic discharge device.

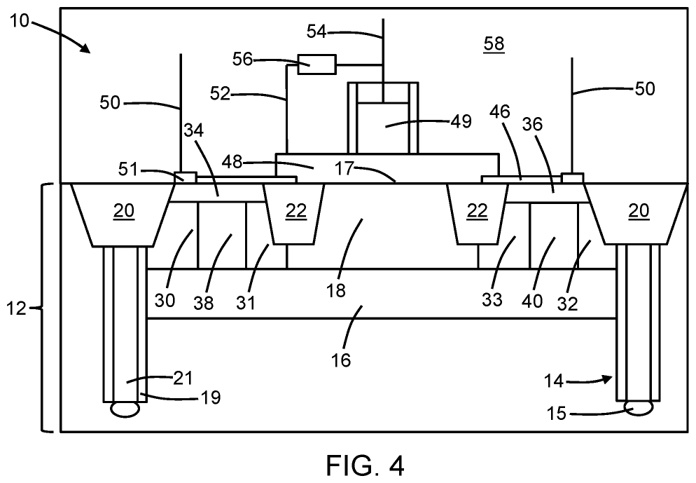

With reference to FIG. 4 in which like reference numerals refer to like features in FIG. 3 and in accordance with alternative embodiments of the invention, the device structure 10 may be modified to add a well 31 similar to well 30 and to add a well 33 similar to well 32. The wells 31, 33 are positioned in the semiconductor layer 18, the well 31 may abut the doped region 34, and the well 33 may abut the doped region 36. The doped region 38 may be positioned in a lateral direction between the well 30 and the well 31 such that the doped region 38 does not abut the shallow trench isolation region 22 adjacent to the doped region 38. Instead, the well 31 abuts the shallow trench isolation region 22 adjacent to the doped region 38 and separates the doped region 40 from the shallow trench isolation region 22. Similarly, the doped region 40 may be positioned in a lateral direction between the well 32 and the well 33 such that the doped region 40 does not abut the shallow trench isolation region 22 adjacent to the well 33. Instead, the well 33 abuts the shallow trench isolation region 22 adjacent to the doped region 40 and separates the doped region 40 from the shallow trench isolation region 22.

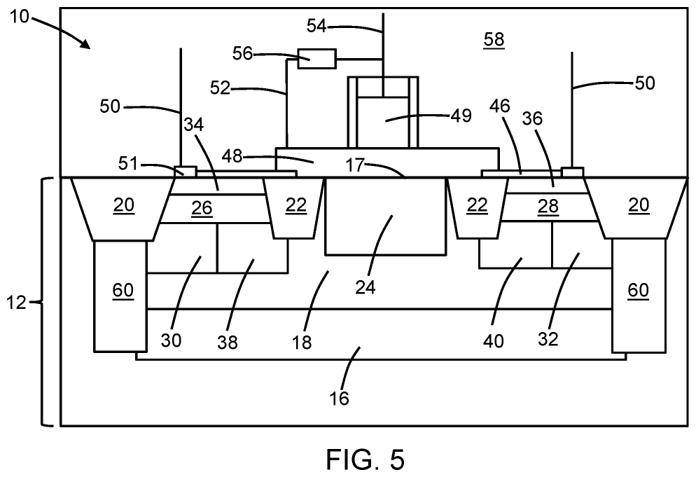

With reference to FIG. 5 in which like reference numerals refer to like features in FIG. 2 and in accordance with alternative embodiments of the invention, the deep trench isolation region 14 of the device structure 10 may be replaced by a well 60 that surrounds the semiconductor layer 18. The well 60 may be formed by a masked ion implantation and may be doped to have the same conductivity type as the deep well 16. In an embodiment, the well 60 may be doped with a concentration of an n-type dopant (e.g., arsenic or phosphorus) to provide n-type conductivity. The well 60 may provide junction isolation, in combination with the deep well 16, for the heterojunction bipolar transistor structure.

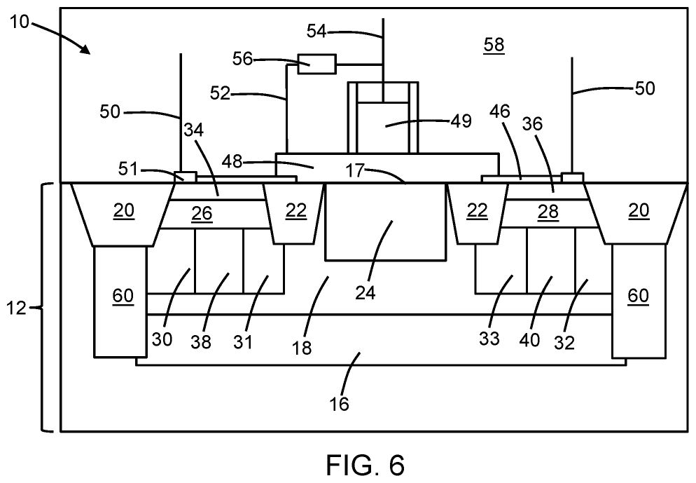

With reference to FIG. 6 in which like reference numerals refer to like features in FIG. 5 and in accordance with alternative embodiments of the invention, the device structure 10 may be further modified to add the well 31 and relocate the doped region 38 to a position laterally between the well 30 and the well 31. The device structure 10 may also be further modified to add the well 33 and relocate the doped region 40 to a position laterally between the well 32 and the well 33.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate a range of +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure for an electrostatic discharge control device, the structure comprising:
a semiconductor substrate including a top surface;
a first shallow trench isolation region positioned in the semiconductor substrate;
a heterojunction bipolar transistor structure including a collector in the semiconductor substrate, an emitter, and a base positioned between a first portion of the collector and the emitter, the collector having a first conductivity type, the collector extending to the top surface of the semiconductor substrate, and the collector wrapping about the first shallow trench isolation region; and
a doped region positioned in the collector adjacent to the first shallow trench isolation region, the doped region having a second conductivity type opposite to the first conductivity type, and a second portion of the collector positioned between the doped region and the top surface of the semiconductor substrate.

2. The structure of claim 1 wherein the doped region abuts the first shallow trench isolation region.

3. The structure of claim 2 wherein the doped region extends beneath a portion of the first shallow trench isolation region.

4. The structure of claim 1 further comprising:
a second shallow trench isolation region positioned in the semiconductor substrate,
wherein the doped region is separated from the second shallow trench isolation region by a third portion of the collector.

5. The structure of claim 4 wherein the third portion of the collector and the doped region are positioned between the first shallow trench isolation region and the second shallow trench isolation region.

6. The structure of claim 1 wherein the doped region is separated from the first shallow trench isolation region by a third portion of the collector.

7. The structure of claim 1 wherein the first shallow trench isolation region extends to the top surface of the semiconductor substrate, and the first shallow trench isolation region is positioned between the first portion of the collector and the second portion of the collector.

8. The structure of claim 1 wherein the second portion of the collector fully separates the doped region from the top surface of the semiconductor substrate.

9. The structure of claim 1 further comprising:
a silicide layer positioned on the second portion of the collector; and
a dielectric layer positioned on the second portion of the collector adjacent to the silicide layer.

10. The structure of claim 9 wherein the dielectric layer is positioned between the silicide layer and the base of the heterojunction bipolar transistor structure.

11. The structure of claim 9 further comprising:
an interconnect structure including an electrical connection coupled to the silicide layer.

12. The structure of claim 1 wherein the base is positioned in a vertical direction between the first portion of the collector and the emitter.

13. The structure of claim 1 further comprising:
a triggering circuit connecting the base to the emitter.

14. The structure of claim 13 wherein the triggering circuit comprises a resistor.

15. The structure of claim 1 further comprising:
a deep trench isolation region surrounding the first portion of the collector.

16. The structure of claim 15 wherein the deep trench isolation region extends to a greater depth in the semiconductor substrate than the collector.

17. The structure of claim 1 further comprising:
a deep well in the semiconductor substrate, the deep well having the first conductivity type,
wherein the collector is positioned between the deep well and the top surface of the semiconductor substrate.

18. The structure of claim 17 wherein the deep well abuts the doped region and the second portion of the collector.

19. The structure of claim 1 further comprising:
a well surrounding the first portion of the collector.

20. A method of forming a structure for an electrostatic discharge control device, the method comprising:
forming a shallow trench isolation region in a semiconductor substrate;
forming a heterojunction bipolar transistor structure including a collector in the semiconductor substrate, an emitter, and a base positioned between a first portion of the collector and the emitter, wherein the collector has a first conductivity type, the collector extends to a top surface of the semiconductor substrate, and the collector wraps about the shallow trench isolation region; and
forming a doped region in the collector adjacent to the shallow trench isolation region, wherein the doped region has a second conductivity type opposite to the first conductivity type, and a second portion of the collector is positioned between the doped region and the top surface of the semiconductor substrate.
